(19) United States
(12) Patent Application Publication
(10) Pub. No.: US 2025/0240956 A1
(43) Pub. Date: Jul. 24, 2025

(54) SEMICONDUCTOR MEMORY DEVICE

(71) Applicant: SK hynix Inc., Icheon-si Gyeonggi-do (KR)

(72) Inventors: Jae Ho KIM, Icheon-si Gyeonggi-do (KR); Hae Chan PARK, Icheon-si Gyeonggi-do (KR); Jae Seok KIM, Icheon-si Gyeonggi-do (KR); Jong Hun KIM, Icheon-si Gyeonggi-do (KR); Sang Heon LEE, Icheon-si Gyeonggi-do (KR)

(73) Assignee: SK hynix Inc., Icheon-si Gyeonggi-do (KR)

(21) Appl. No.: 18/772,461

(22) Filed: Jul. 15, 2024

(30) Foreign Application Priority Data
Jan. 22, 2024 (KR) 10-2024-0009495

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

Provided herein is a semiconductor memory device. The semiconductor memory device includes a gate stacked body enclosing a plurality of channel pillars and a plurality of support structures extending through a section of the gate stacked body near an edge of the gate stacked body.

### CROSS-REFERENCE TO RELATED APPLICATION

The present application claims priority under 35 U.S.C. § 119 (a) to Korean patent application number 10-2024-0009495 filed on Jan. 22, 2024, in the Korean Intellectual Property Office, the entire contents of which application is incorporated herein by reference.

### BACKGROUND

### 1. Technical Field

Various embodiments of the present disclosure generally relate to a semiconductor memory device, including but not limited to a three-dimensional (3D) semiconductor memory device.

### 2. Related Art

A semiconductor memory device may be included in a small electronic device as well as in electronic systems in various applications such as automobiles, medical fields, or data centers. A growing demand for semiconductor memory devices exists.

The semiconductor memory device includes a memory cell for storing data. A 3D semiconductor memory device includes a plurality of memory cells arranged in three dimensions, such that the 3D semiconductor memory device may advantageously achieve a larger capacity compared to a two-dimensional (2D) semiconductor memory device.

The integration degree of memory cells in the 3D semiconductor memory device can be improved by increasing the quantity of stacked memory cells. As the quantity of stacked memory cells increases, the quantity of stacked conductive layers coupled to the memory cell increases.

### SUMMARY

An embodiment of the present disclosure may provide for a semiconductor memory device. The semiconductor memory device may include a first interlayer insulating layer including a surface extending in a first direction and a second direction and facing a third direction, a second interlayer insulating layer spaced apart from the first interlayer insulating layer in the third direction, a plurality of channel pillars extending through the first interlayer insulating layer and the second interlayer insulating layer, a first sub-gate stacked body enclosing the plurality of channel pillars between the first interlayer insulating layer and the second interlayer insulating layer, a plurality of support structures arranged in a row near an edge of the first sub-gate stacked body and extending through the first interlayer insulating layer and the first sub-gate stacked body, and a second sub-gate stacked body enclosing the plurality of channel pillars between the first sub-gate stacked body and the second interlayer insulating layer and covering the plurality of support structures.

An embodiment of the present disclosure may provide for a semiconductor memory device. The semiconductor memory device may include a first interlayer insulating layer including a surface extending in a first direction and a second direction and facing a third direction, a second interlayer insulating layer spaced apart from the first interlayer insulating layer in the third direction, a plurality of conductive layers alternately arranged with a plurality of intervening interlayer insulating layers in the third direction and located between the first interlayer insulating layer and the second interlayer insulating layer, a first slit and a second slit extending, in the third direction, through the first interlayer insulating layer, the plurality of conductive layers, the plurality of intervening interlayer insulating layers, and the second interlayer insulating layer, the first slit spaced apart from the second slit spaced in the first direction, a plurality of first support structures forming a first row near the first slit and a plurality of second support structures forming a second row near the second slit, wherein the plurality of first support structures and the plurality of second support structures extend through a first subset of the conductive layers nearest to the first interlayer insulating layer and a second subset of the conductive layers is disposed over a surface of each of the plurality of first support structures and a surface of each of the plurality of second support structures, and a plurality of channel pillars disposed between the first row and the second row and extending, in the third direction, through the plurality of conductive layers, the plurality of intervening interlayer insulating layers, and the second interlayer insulating layer.

An embodiment of the present disclosure may provide for a semiconductor memory device. The semiconductor memory device may include a stack comprising a first subset of layers and a second subset of layers, wherein the stack extends in a first direction between a first slit and a second slit, wherein the first slit and the second slit extend in a second direction; a plurality of channel pillars extending through the stack in the third direction; a first plurality of support structures disposed between the first slit and the plurality of channel pillars and extending through the first subset of layers in the third direction; and a second plurality of support structures disposed between the second slit and the plurality of channel pillars and extending through the first subset of layers in the third direction; wherein the second subset of layers is disposed in the third direction over the first subset of layers, the plurality of first support structures, and the plurality of second support structures.

### BRIEF DESCRIPTION OF THE DRAWINGS

FIG. 1A and FIG. 1B are circuit diagrams illustrating a memory cell array of a semiconductor memory device according to an embodiment of the present disclosure.

FIG. 2A and FIG. 2B are diagrams illustrating a semiconductor memory device according to an embodiment of the present disclosure.

FIG. 3 is a sectional view illustrating a semiconductor memory device according to an embodiment of the present disclosure.

FIG. 4A illustrates the layout of a gate stacked body at level LV1 shown in FIG. 3, and FIG. 4B illustrates the layout of the gate stacked body at level LV2 shown in FIG. 3.

FIG. 5A to FIG. 5C are sectional views illustrating a semiconductor memory device according to an embodiment of the present disclosure.

FIG. 6A to FIG. 6F are sectional views illustrating a semiconductor memory device formed utilizing a method of manufacturing a semiconductor memory device according to an embodiment of the present disclosure.

FIG. 7A and FIG. 7B are sectional views illustrating a semiconductor memory device formed utilizing processes of manufacturing a semiconductor memory device according to an embodiment excluding support structures.

FIG. 8 is a block diagram illustrating an electronic system according to an embodiment of the present disclosure.

### DETAILED DESCRIPTION

Specific structural or functional descriptions of embodiments are provided as examples to describe the concepts of the present disclosure. The embodiments according to the concepts of the present disclosure should not be construed as limited to embodiments described and may be modified or carried out in various forms not limited to the embodiments described in this specification.

Terms such as “first” and “second” are used to distinguish between various elements and do not imply size, order, priority, quantity, or importance of the elements. These elements are not limited by these terms. Terms such as “vertical,” “horizontal,” “over,” “below,” “on,” “side,” “upper,” “lower,” “uppermost,” “level,” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials for the areas.

Various embodiments of the present disclosure are directed to a semiconductor memory device and a method of manufacturing the semiconductor memory device, which can improve structural stability.

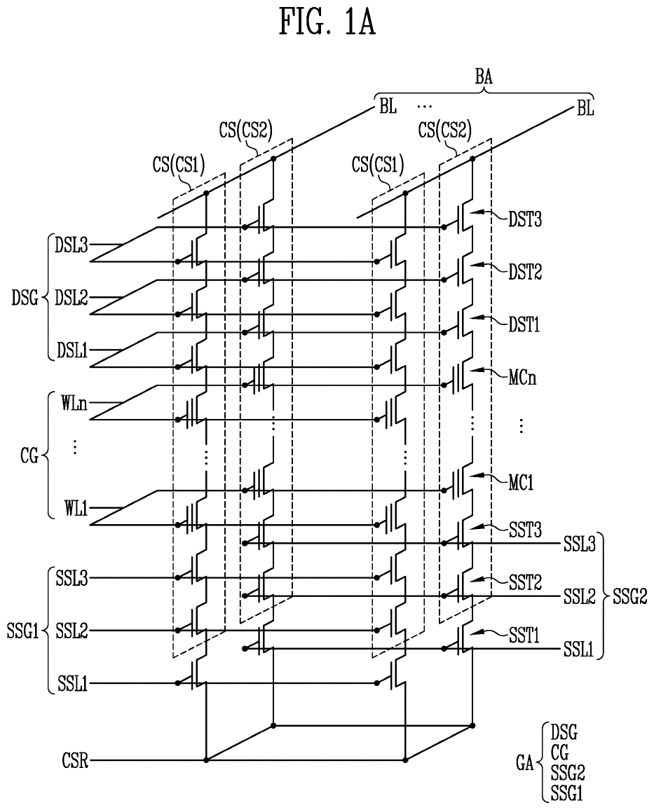

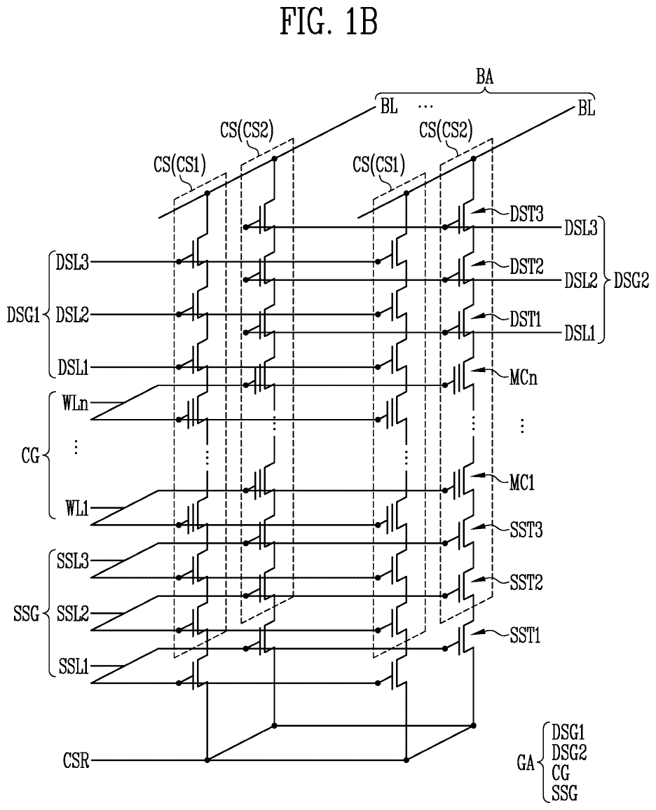

FIG. 1A and FIG. 1B are circuit diagrams illustrating a memory cell array of a semiconductor memory device according to an embodiment of the present disclosure.

Referring to FIG. 1A and FIG. 1B, the memory cell array of the semiconductor memory device includes a plurality of memory cell strings CS. The plurality of memory cell strings CS forms a plurality of rows and columns. The plurality of memory cell strings CS is coupled to a gate array GA, a bit line array BA, and a common source layer CSR.

The plurality of memory cell strings CS coupled to the common source layer CSR form a plurality of rows and columns. A voltage for discharging a channel layer potential of the memory cell string CS is applied to the common source layer CSR.

The bit line array BA includes a plurality of bit lines BL. The memory cell strings of a corresponding row are coupled to each bit line BL. A voltage for precharging the channel layer of a corresponding memory cell string CS is applied to the bit line BL.

Each memory cell string CS includes a channel layer coupled to the bit line BL and the common source layer CSR. The memory cell string CS includes at least one source select transistor, for example, SST1, SST2, and SST3, a plurality of memory cells MC1 to MCn, where n is a natural number equal to or greater than 2, and at least one drain select transistor, for example, DST1, DST2, and DST3. At least one source select transistor, the plurality of memory cells MC1 to MCn, and at least one drain select transistor are connected in series by the channel layer.

A gate array GA includes a source select gate group SSG1, SSG2, or SSG, a cell gate group CG, and a drain select gate group DSG, DSG1, or DSG2. The source select gate group SSG1, SSG2, or SSG includes at least one source select line, for example, SSL1, SSL2, and SSL3. The cell gate group CG includes a plurality of word lines WL1 to WLn. The drain select gate group DSG, DSG1, or DSG2 includes at least one drain select line, for example, DSL1, DSL2, and DSL3. Each source select line is used as a gate electrode of a corresponding source select transistor, each word line is used as a gate electrode of a corresponding memory cell, and each drain select line is used as a gate electrode of a corresponding drain select transistor.

Each of the plurality of word lines WL1 to WLn is configured to control multiple rows of memory cell strings. The multiple rows of memory cell strings are divided into two or more groups. In an embodiment, the multiple rows of memory cell strings controlled by the cell gate group CG include a first group of first memory cell strings CS1 and a second group of second memory cell strings CS2. At least one of the source select gate group and the drain select gate group are configured to control the multiple rows of memory cell strings controlled by the cell gate group CG.

Referring to FIG. 1A, according to an embodiment, the first group of first memory cell strings CS1 is coupled to the source select line SSL1, SSL2, or SSL3 of the first source select gate group SSG1, and the second group of second memory cell strings CS2 is coupled to the source select line SSL1, SSL2, or SSL3 of the second source select gate group SSG2. The first source select group SSG1 and the second source select gate group SSG2 are spaced apart from each other to selectively control a corresponding group of memory cell strings. For example, each drain select line DSL1, DSL2, and DSL3 of the drain select group DSG is coupled to the first group of first memory cell strings CS1 and the second group of second memory cell strings CS2.

Referring to FIG. 1B, according to an embodiment, each source select line SSL1, SSL2, and SSL3 of the source select group SSG is coupled to the first group of first memory cell strings CS1 and the second group of second memory cell strings CS2. For example, the first memory cell strings CS1 of the first group are coupled to the drain select lines DSL1, DSL2, and DSL3 of the first drain select gate group DSG1, and the second memory cell strings CS2 of the second group are coupled to the drain select lines DSL1, DSL2, and DSL3 of the second drain select gate group DSG2. The first drain select gate group DSG1 and the second drain select gate group DSG2 are spaced apart from each other to selectively control a corresponding group of memory cell strings.

Although not shown in the drawing, according to an embodiment, the first group of first memory cell strings CS1 and the second group of second memory cell strings CS2 may be separately coupled to the first source select gate group SSG1 and the second source select gate group SSG2 that are separated from each other as shown in FIG. 1A and may be separately coupled to the first drain select gate group DSG1 and the second drain select gate group DSG2 that are separated from each other as shown in FIG. 1B.

Referring to FIG. 1A and FIG. 1B, the gate array GA includes a plurality of conductive layers that are stacked and spaced apart from each other. The plurality of conductive layers may be separated into a plurality of gate stacked bodies by a slit.

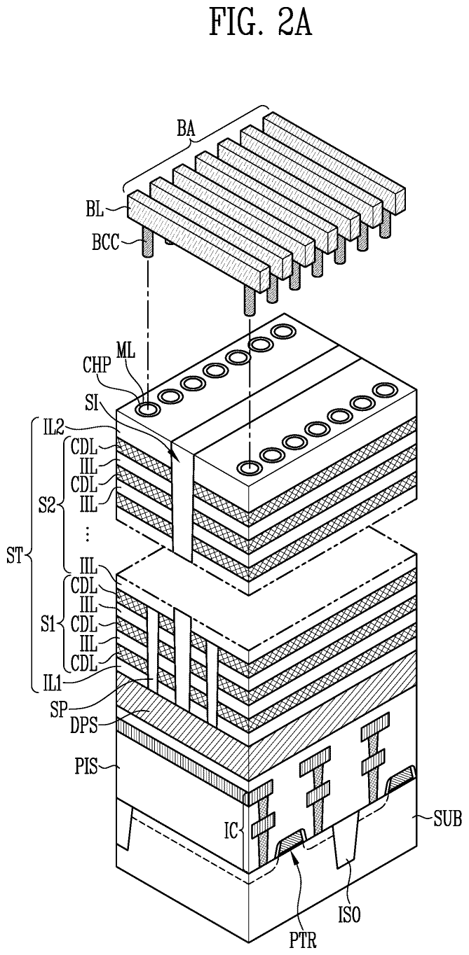

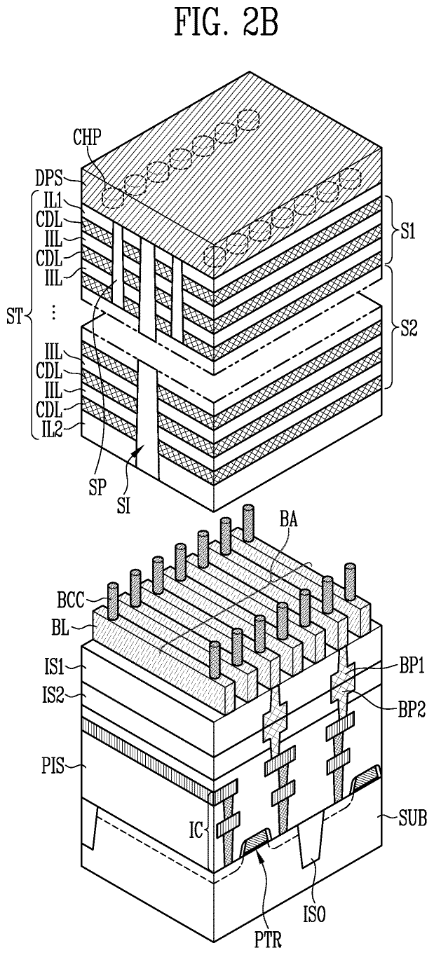

FIG. 2A and FIG. 2B are diagrams illustrating a semiconductor memory device according to an embodiment of the present disclosure.

Referring to FIG. 2A and FIG. 2B, the semiconductor memory device includes a plurality of gate stacked bodies ST that are separated from each other by a slit SI. Each gate stacked body ST is disposed between the bit line array BA and the doped semiconductor structure DPS. A plurality of channel pillars CHP extends through the gate stacked body ST. The semiconductor memory device includes a memory layer ML interposed between each channel pillar CHP and the gate stacked body ST.

The doped semiconductor structure DPS includes at least one doped semiconductor layer. The doped semiconductor structure DPS includes at least one of a first conductivity type doped area including an n-type impurity as a majority carrier and a second conductivity type doped area including a p-type impurity as a majority carrier. The first conductivity type doped area is a common source area, and the second conductivity type doped area is a well area. The first conductivity type doped area of the doped semiconductor structure DPS forms the common source layer CSR described with reference to FIG. 1A and FIG. 1B.

The bit line BL of the bit line array BA is coupled to a corresponding channel pillar CHP via a bit line contact structure BCC.

The gate stacked body ST includes a first interlayer insulating layer IL1, a second interlayer insulating layer IL2, a plurality of conductive layers CDL, and a plurality of intervening interlayer insulating layers IIL. The first interlayer insulating layer IL1 is disposed adjacent to the doped semiconductor structure DPS, and the second interlayer insulating layer IL2 is disposed adjacent to the bit line array BA. The plurality of conductive layers CDL is alternately disposed with the plurality of intervening interlayer insulating layers IIL, which are disposed between the first interlayer insulating layer IL1 and the second interlayer insulating layer IL2. Each of the plurality of conductive layers CDL may include various conductive materials such as a doped semiconductor layer or a metal layer. The doped semiconductor layer may include a doped silicon layer. The metal layer may include tungsten, copper, molybdenum, and so forth. Each conductive layer CDL may further include a conductive metal nitride layer. The conductive metal nitride layer may include titanium nitride, tantalum nitride, and so forth. The conductive metal nitride layer may serve as a barrier layer. Each of the first interlayer insulating layer IL1, the second interlayer insulating layer IL2, and the plurality of intervening interlayer insulating layers IIL may include an insulating material such as a silicon oxide layer or a silicon oxynitride layer.

An edge of each gate stacked body ST is adjacent to the slit SI and extends along the slit SI. A support structure SP is disposed inside the edge of the gate stacked body ST.

The plurality of conductive layers CDL and the plurality of intervening interlayer insulating layers IIL of the gate stacked body ST are divided into a first sub-gate stacked body S1 and a second sub-gate stacked body S2. A first subset of the plurality of conductive layers CDL and the plurality of intervening interlayer insulating layers IIL, which first subset is adjacent to the first interlayer insulating layer IL1, comprises the first sub-gate stacked body S1, while a second subset of the plurality of conductive layers CDL and the plurality of intervening interlayer insulating layers IIL, which second subset is adjacent to the second interlayer insulating layer IL2, comprises the second sub-gate stacked body S2. The support structure SP extends through the first sub-gate stacked body S1. The second sub-gate stacked body S2 extends to cover the support structures SP.

Each channel pillar CHP includes the channel layer of the memory cell string CS described with reference to FIG. 1A and FIG. 1B. The channel layer of the channel pillar CHP is electrically connected to a corresponding bit line BL via the bit line coupling structure BCC. The channel layer of the channel pillar CHP includes a contact surface that is in contact with or touches the doped semiconductor structure DPS. The contact surface is between a sidewall of the channel pillar CHP and the doped semiconductor structure DPS or between an end of the channel pillar CHP and the doped semiconductor structure DPS. Referring to FIG. 2B, the end of the channel pillar CHP protrudes into the doped semiconductor structure DPS whereas the memory layer does not protrude into the doped semiconductor structure DPS. The doped semiconductor structure DPS may include grooves or slots into which the ends of the channel pillar CHP are inserted. In this example, a contact surface between the doped semiconductor structure DPS and the channel layer is located on or at the end of the channel pillar CHP.

Referring to FIG. 2A and FIG. 2B, a peripheral circuit structure of the semiconductor memory device includes a plurality of transistors PTR. The plurality of transistors PTR is near the doped semiconductor structure DPS as shown in FIG. 2A or near the bit line array BA as shown in FIG. 2B. Each transistor PTR is disposed in an active area of a semiconductor substrate SUB partitioned by an isolation layer ISO.

The plurality of transistors PTR may be covered with a peripheral insulating structure PIS on the semiconductor substrate SUB. A plurality of interconnections IC are disposed in the peripheral insulating structure PIS. The plurality of interconnections IC include at least one of a plurality of conductive lines and a plurality of conductive contacts.

The bit line array BA, the gate stacked body ST, and the doped semiconductor structure DPS may be arranged in various ways on the peripheral insulating structure PIS.

Referring to FIG. 2A, the doped semiconductor structure DPS is disposed between the gate stacked body ST and the peripheral insulating structure PIS. The doped semiconductor structure DPS and the gate stacked body ST are disposed between the bit line array BA and the peripheral insulating structure PIS.

Referring to FIG. 2B, the bit line array BA is disposed between the gate stacked body ST and the peripheral insulating structure PIS. The bit line array BA and the gate stacked body ST are disposed between the doped semiconductor DPS and the peripheral insulating structure PIS.

Each transistor PTR shown in FIG. 2A and FIG. 2B is coupled to the memory cell array via a corresponding interconnection IC. According to an embodiment, the plurality of transistors PTR include a transistor of a page buffer and a transistor of a pass circuit. The transistor of the page buffer is coupled to the bit line BL via the interconnection IC, and the transistor of the pass circuit is coupled to one of the conductive layers CDL via one of the interconnections IC.

A structure for coupling the interconnections IC and the memory cells array may vary. According to an embodiment, as shown in FIG. 2B, the semiconductor memory device includes a first conductive bonding structure BP1 and a second conductive bonding structure BP2 that couple the interconnection IC and the memory cell array.

Referring to FIG. 2B, the first conductive bonding structure BP1 is disposed in a first intervening insulation structure IS1 between the bit line array BA and the peripheral insulating structure PIS. The first conductive bonding structure BP1 is coupled to a corresponding bit line BL. The second conductive bonding structure BP2 is disposed in a second intervening insulation structure IS2 between the first intervening insulation structure IS1 and the peripheral insulating structure PIS. The second conductive bonding structure BP2 is coupled to a corresponding interconnection IC. The second conductive bonding structure BP2 is bonded to a corresponding first conductive bonding structure BP1.

FIG. 2A and FIG. 2B illustrate a partial area of the plurality of conductive layers CDL along the edge of the gate stacked body ST. The plurality of conductive layers CDL extend in a horizontal direction from the edge of the gate stacked body ST away from the slit SI and form a source select gate group, a cell gate group, and a drain select gate group. The width of the slit SI and channel pillar CHP may narrow from the second interlayer insulating layer IL2 toward the first interlayer insulating layer IL1. Thus, the support force provided by the channel pillar CHP decreases in the direction from the second interlayer insulating layer IL2 toward the first interlayer insulating layer IL1, or the least amount of support is provided at the first interlayer insulating layer IL1. The support force provided by a channel pillar CHP decreases the closer the channel pillar CHP is to the slit SI. The support structure SP is disposed between the channel pillars and the slit SI to increase support force and offset a reduction in support force caused by the channel pillar CHP. For example, the support structure SP is formed to extend through at least the first interlayer insulating layer IL1 and the source select gate group adjacent to the first interlayer insulating layer IL1. The support structure SP is shorter than the channel pillar CHP, and is covered with the second sub-gate stacked body S2. Because the aspect ratio of the support structure SP is reduced compared to the aspect ratio of the channel pillar CHP, an area occupied by the support structure SP may be reduced. When a distance between the slit SI and a nearest channel pillar CHP is not excessively increased, a target placement margin for the location of the support structure SP may be achieved or obtained.

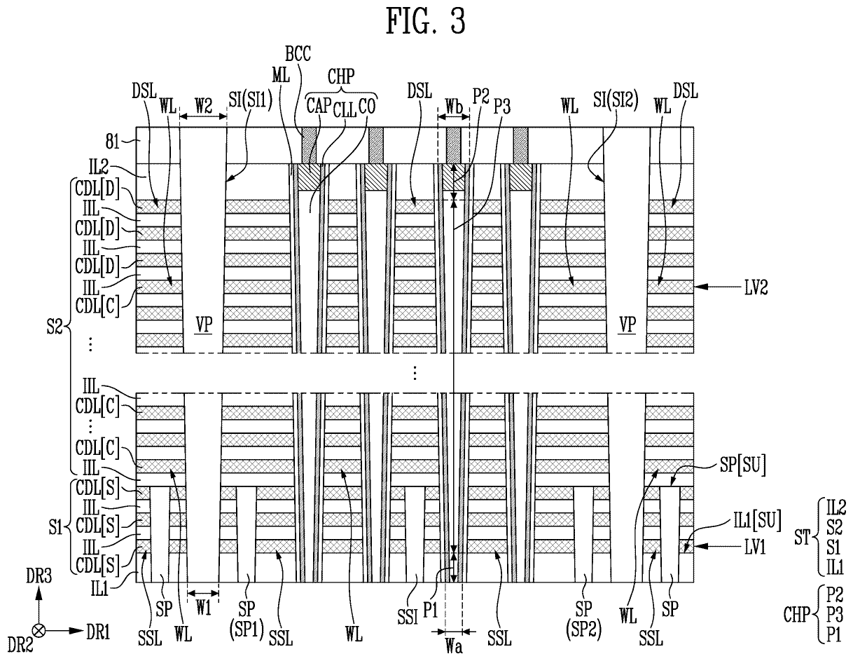

FIG. 3 is a sectional view illustrating a semiconductor memory device according to an embodiment of the present disclosure.

Referring to FIG. 3, a surface IL1[SU] of the first interlayer insulating layer IL1 extends in a first direction DR1 and a second direction DR2 that are different from each other, for example, in the XY plane, and faces in a third direction DR3. The first direction DR1, the second direction DR2, and the third direction DR3 may correspond to the X-axis direction, Y-axis direction, and Z-axis direction, respectively, of an XYZ coordinate system.

The second interlayer insulating layer IL2 is spaced apart from the first interlayer insulating layer IL1 in the third direction DR3. The plurality of conductive layers CDL[S], CDL[C], and CDL[D] and the plurality of intervening interlayer insulating layers IIL are disposed between the first interlayer insulating layer IL1 and the second interlayer insulating layer IL2. The plurality of conductive layers CDL are alternately arranged with the plurality of intervening interlayer insulating layers IIL in the third direction DR3 as shown in FIG. 3.

The second interlayer insulating layer IL2 is covered with an insulating layer 81. The bit line contact structure BCC is disposed inside the insulating layer 81.

The plurality of conductive layers CDL[S], CDL[C], and CDL[D] includes at least one source select gate layer CDL[S], a plurality of cell gate layers CDL[C], and at least one drain select gate layer CDL[D]. FIG. 3 illustrates three source select gate layers CDL[S] and three drain select gate layers CDL[D]. The present disclosure is not limited to the example of FIG. 3.

The first interlayer insulating layer IL1, the plurality of conductive layers CDL[S], CDL[C], and CDL[D], the plurality of intervening interlayer insulating layers IIL, and the second interlayer insulating layer IL2 are separated into a plurality of gate stacked bodies ST by a plurality of slits SI.

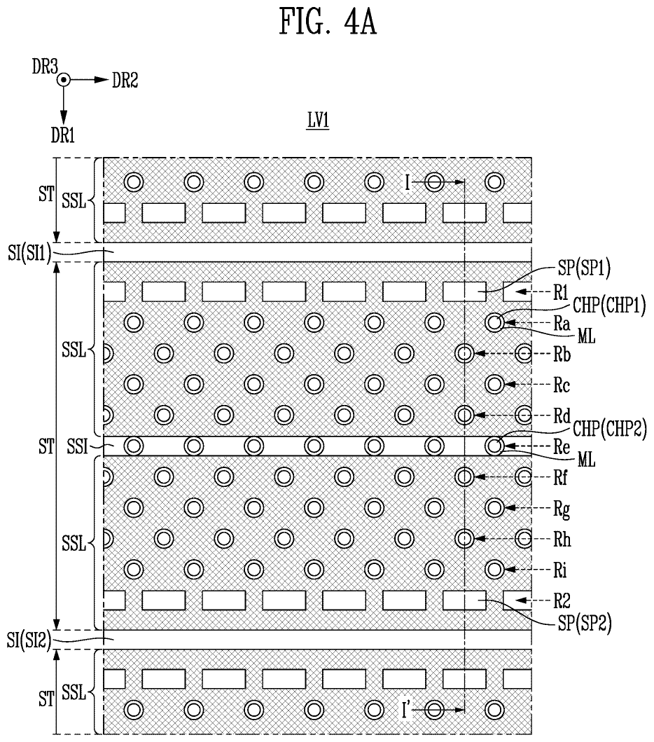

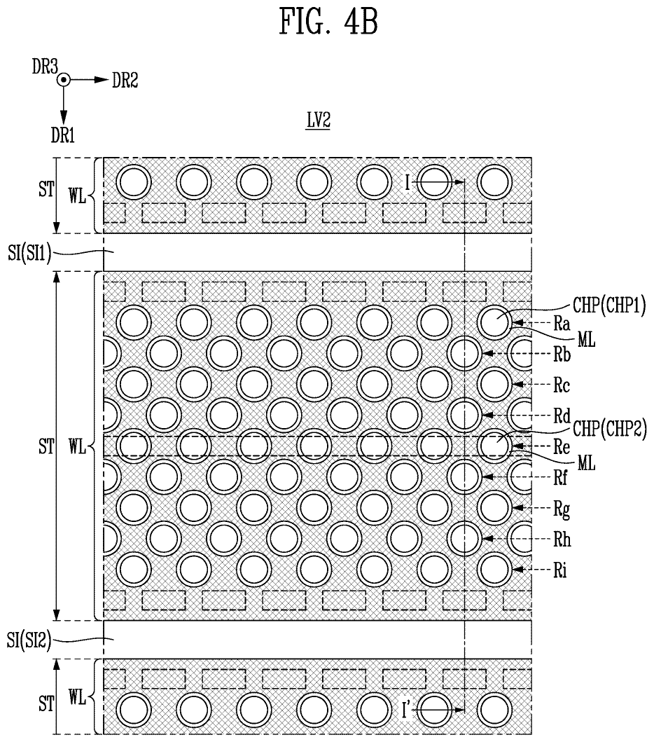

FIG. 4A shows the layout of the gate stacked body ST at level LV1 shown in FIG. 3, and FIG. 4B shows the layout of the gate stacked body ST at level LV2 shown in FIG. 3. The level LV1 is a level where the source select gate layer CDL[S] is disposed, and the level LV2 is a level where a cell gate layer CDL[C] is disposed. FIG. 3 corresponds to a sectional view of the semiconductor memory device taken along line I-I′ of FIG. 4A or FIG. 4B.

Referring to FIG. 3, FIG. 4A, and FIG. 4B, the plurality of gate stacked bodies ST is arranged between a pair of slits SI in the first direction DR1. Each slit SI extends in the third direction DR3 to pass through the first interlayer insulating layer IL1, the plurality of conductive layers CDL[S], CDL[C], and CDL[D], the plurality of intervening interlayer insulating layers IIL, the second interlayer insulating layer IL2, and the insulating layer 81. Each slit SI extends in the second direction DR2 and may be formed in various shapes such as a straight line or a zigzag or diagonal shape. A vertical structure VP is disposed in each slit SI. A material forming the vertical structure VP may vary. According to an embodiment, the vertical structure VP may include an insulating layer. According to an embodiment, the vertical structure VP may include at least one of a conductive layer and a semiconductor layer in addition to the insulating layer.

The plurality of slits SI includes a first slit SI1 and a second slit SI2 that are consecutive in the first direction DR1. Each gate stacked body ST is disposed between the first slit SI1 and the second slit SI2. The edges of the gate stacked body ST extend along an edge of the first slit SI and an edge of the second slit SI2.

The plurality of support structures SP are disposed in the gate stacked body ST. The plurality of support structures SP extends through the first interlayer insulating layer IL1 and the first sub-gate stacked body S1. In an embodiment, among the plurality of conductive layers CDL[S], CDL[C], and CDL[D], the source select gate layers CDL[S] are included in the first sub-gate stacked body S1.

A source select gate separation structure SSI extends through each source select gate layer CDL[S]. The source select gate separation structure SSI may be formed of various insulating materials such as a silicon oxide layer. The source select gate separation structure SSI is disposed between the first slit SI1 and the second slit SI2. Each source select gate layer CDL[S] is separated into source select lines SSL between the first slit SI1 and the second slit SI2. The source select gate separation structure SSI extends through the first interlayer insulating layer IL1.

The plurality of support structures SP extends through the source select gate layers CDL[S] of the first sub-gate stacked body ST1 near the edge of the gate stacked body ST and extends through the first interlayer insulating layer IL1. For example, the plurality of support structures SP may be disposed in the gate stacked body ST between the slit SI and the nearest row of channel pillars. The plurality of support structures SP may be formed of various insulating materials such as a silicon oxide layer. Each support structure SP may have various sectional shapes such as square, rectangular, circular, oval, triangular, or polygonal. The sidewall of the support structure SP is enclosed or surrounded by the source select gate layers CDL[S] forming the conductive layers of the first sub-gate stacked body S1.

The plurality of support structures SP includes a plurality of first support structures SP1 forming a first row R1 and a plurality of second support structures SP2 forming a second row R2. The plurality of first support structures SP1 of the first row R1 is near the first slit SI1 and arranged along the second direction DR2. The plurality of second support structures SP2 of the second row R2 is near the second slit SI2 and arranged along the second direction DR2. For example, the first row R1 of the first support structures SP1 may advantageously be disposed between the slit SI1 and the nearest row Ra of channel pillars CHP to the slit SI1.

The source select line SSL adjacent to the first slit SI1 extends between the first support structures SP1 in the second direction DR2, and extends between the first slit SI1 and the first row R1 in the first direction DR1. The source select line SSL adjacent to the second slit SI2 extends between the second support structures SP2 in the second direction DR2, and extends between the second slit SI2 and the second row R2 in the first direction DR1.

Among the plurality of conductive layers CDL[S], CDL[C], and CDL[D], the plurality of cell gate layers CDL[C] and the drain select gate layers CDL[D] are included in the second sub-gate stacked body S2. The plurality of cell gate layers CDL[C] are disposed between the first sub-gate stacked body S1 and the second interlayer insulating layer IL2 and are stacked spaced apart from each other in the third direction DR3. The plurality of cell gate layers CDL[C] are disposed between the first slit SI1 and the second slit SI2 and form the plurality of word lines WL. The drain select gate layers CDL[D] are disposed between the plurality of cell gate layers CDL[C] and the second interlayer insulating layer IL2 and are stacked spaced apart from each other in the third direction DR3. Each of the drain select gate layers CDL[D] is disposed between the first slit SI1 and the second slit SI2 and forms the drain select lines DSL.

Each of the plurality of word lines WL and the drain select lines DSL is continuous without separation between the first slit SI1 and the second slit SI2 and includes a portion disposed over the source select gate separation structure SSI in the third direction DR3 and a portion disposed over the plurality of support structures SP in the third direction DR3. In an embodiment, a surface SP [SU] of the support structure SP faces the third direction DR3 and is below a section of each of the plurality of cell gate layers CDL[C] and drain select gate layers CDL[D].

The plurality of channel pillars CHP extends through the first interlayer insulating layer IL1 of each gate stacked body ST and extends in the third direction DR3 through the first sub-gate stacked body S1, the second sub-gate stacked body S2, and the second interlayer insulating layer IL2. The plurality of channel pillars CHP are formed in a plurality of rows Ra to Ri between the first row R1 of first support structures SP1 and the second row R2 of second support structures SP2. The number of the plurality of rows Ra to Ri may be designed in various ways not limited to the example in the drawings. The arrangement of the plurality of channel pillars CHP may vary. In an embodiment, the plurality of channel pillars CHP may be arranged in a zigzag or diagonal fashion between the first row R1 and the second row R2.

Each channel pillar CHP includes a channel layer CLL. The channel layer CLL may be formed of a semiconductor material such as silicon (Si), germanium (Ge), or a mixture thereof, which may be used for a channel area of the memory cell string. The channel layer CLL may have various structures. In an embodiment, the channel layer CLL may be formed in a tubular shape. In this example, the channel pillar CHP includes a core insulating layer CO and a capping pattern CAP, which are disposed in a central area within a tubular pattern of the channel layer CLL. The capping pattern CAP may include a doped semiconductor layer containing at least one of an n-type impurity and a p-type impurity. In an embodiment, the capping pattern CAP may include an n-type doped silicon containing the n-type impurity as a majority carrier.

The memory layer ML extends along the sidewall of a channel pillar CHP. The memory layer ML is interposed in the third direction DR3 between the first interlayer insulating layer IL1 and the second interlayer insulating layer IL2. The memory layer ML is surrounded by the first sub-gate stacked body S1 and the second sub-gate stacked body S2 and surrounds the channel pillar CHP. The memory layer ML includes a tunnel insulating layer, a data storage layer, and a blocking insulating layer. The tunnel insulating layer extends along an outer wall of the channel layer CLL. The tunnel insulating layer TI may include an insulating material such as a silicon oxide layer. The data storage layer is interposed between the gate stacked body ST and the tunnel insulating layer. In an embodiment, the data storage layer extends continuously along an outer wall of the tunnel insulating layer. According to an embodiment, the data storage layer is divided into a plurality of data storage patterns spaced apart from each other in the third direction DR3, and each of the plurality of data storage patterns is disposed at a different level where the plurality of conductive layers CDL[S], CDL[C], and CDL[D] are disposed. The data storage layer may be formed of a material layer that stores changed data using Fowler-Nordheim tunneling. In an embodiment, the data storage layer is formed of a charge trap insulating layer, a floating gate layer, or an insulating layer containing conductive nanodots. The charge trap insulating layer may include a silicon nitride layer. The blocking insulating layer is interposed between the gate stacked body ST and the data storage layer. The blocking insulating layer may include at least one of a silicon dioxide layer (SiO₂) and a high-k dielectric layer having a higher dielectric constant than the silicon dioxide layer. The high-k dielectric layer may include an aluminum oxide layer, a hafnium oxide layer, or the like.

The plurality of channel pillars CHP includes a plurality of first channel pillars CHP1 and a plurality of second channel pillars CHP2. The plurality of first channel pillars CHP1 is arranged on both sides of the source select gate separation structure SSI. The first channel pillars CHP1 are arranged in plurality of rows Ra, Rb, Rc, Rd, Rf, Rg, Rh, and Ri. The plurality of second channel pillars CHP2 are arranged in a row Re disposed over the source select gate separation structure SSI. Each of the plurality of first channel pillars CHP1 is used as the channel area of the memory cell string. In an embodiment, each of the plurality of second channel pillars CHP2 is used as the channel area of the memory cell string. According to an embodiment, each of the plurality of second channel pillars CHP2 is a dummy pillar that does not participate in the data processing operations of the semiconductor memory device.

The sidewall of each first channel pillar CHP1 is enclosed or surrounded by the first interlayer insulating layer IL1, the source select lines SSL, the word lines WL, the drain select lines DSL, and the second interlayer insulating layer IL2. The sidewall of each second channel pillar CHP2 is enclosed or surrounded by the word lines WL, the drain select line DSL, and the second interlayer insulating layer IL2. Each of the word lines WL and the drain select lines DSL extends over the source select gate separation structure SSI.

Each channel pillar CHP includes a first portion P1 extending through the first interlayer insulating layer IL1, a second portion P2 extending through the second interlayer insulating layer IL2, and a third portion P3 extending between the first portion P1 and the second portion P2. In the example of FIG. 3, a width Wa of the first portion P1 is narrower than a width Wb of the second portion P2. In an embodiment, the width Wa of the first portion P1 measured in the first direction DR1 is narrower than the width Wb of the second portion P2 measured in the first direction DR1. The third portion P3 has a narrower width closer to the first portion P1 in the first sub-gate stacked body S1 than the width closer to the second portion P2.

The width of each of the plurality of slits SI is narrower closer to the first interlayer insulating layer IL1. According to an embodiment, each slit SI has a first width W1 in the first direction DR1 within the first interlayer insulating layer IL1 and has a second width W2 in the first direction DR1 within the insulating layer 81. The first width W1 is typically narrower than the second width W2.

As described above, because at least one of the channel pillar CHP and the slit SI are narrower closer to the first interlayer insulating layer IL1, a target placement margin for the location of support structure SP is achieved within the first sub-gate stacked body S1 adjacent to the first interlayer insulating layer IL1.

The memory cell array illustrated in FIG. 1A may be implemented according to the semiconductor memory device illustrated in FIG. 3, FIG. 4A, and FIG. 4B.

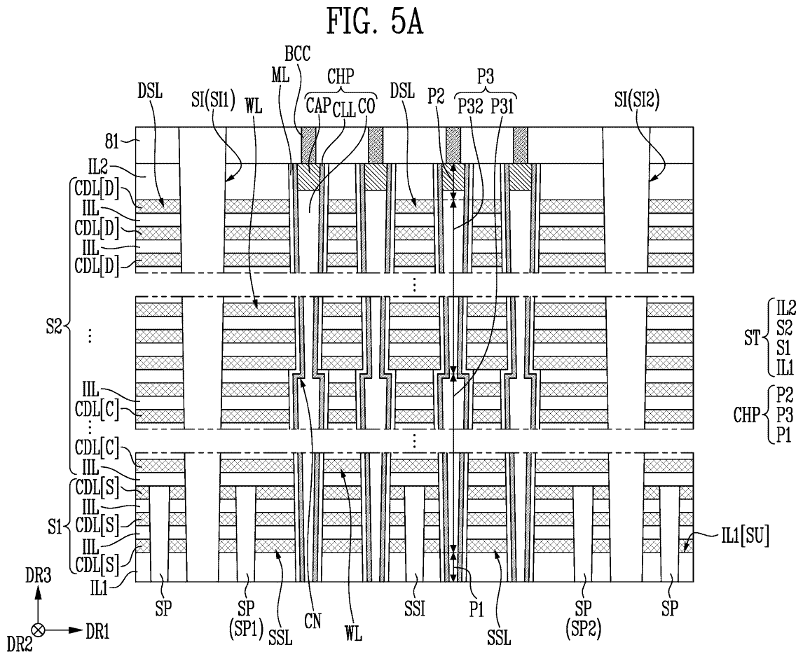

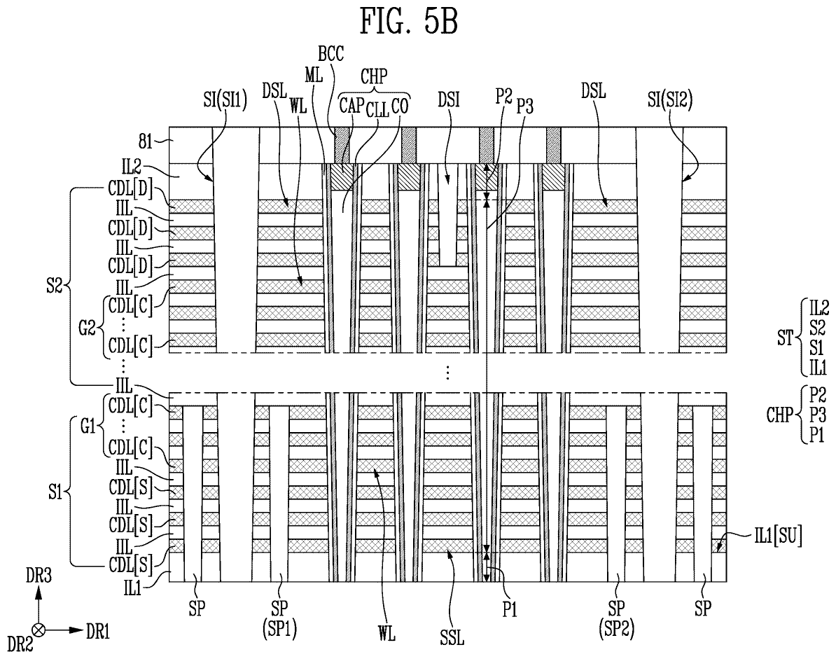

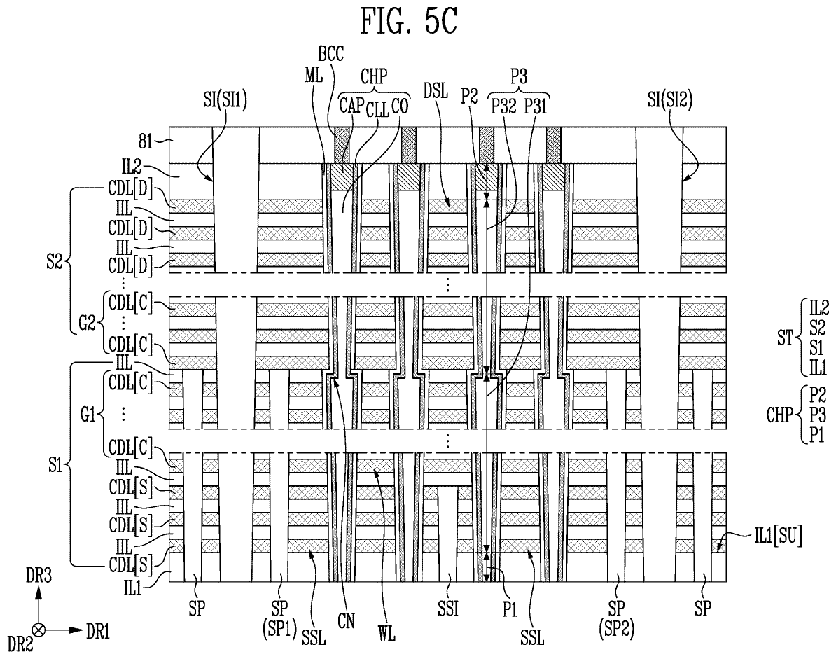

FIG. 5A to FIG. 5C are sectional views illustrating a semiconductor memory device according to an embodiment of the present disclosure.

Referring to FIG. 5A to FIG. 5C, the plurality of gate stacked bodies ST are partitioned by the plurality of slits SI. The plurality of slits SI include a first slit SI1 and a second slit SI2 that are consecutive in the first direction DR1.

Each gate stacked body ST is disposed between the first slit SI1 and the second slit SI2 that are consecutive in the first direction DR1. A first edge of the gate stacked body ST is adjacent to an edge of the first slit SI1 and a second edge of the gate stacked body ST is adjacent to an edge of the second slit SI2. The gate stacked body ST includes a first interlayer insulating layer IL1, a second interlayer insulating layer IL2, a first sub-gate stacked body S1 between the first interlayer insulating layer IL1 and the second interlayer insulating layer IL2, and a second sub-gate stacked body S2 between the first sub-gate stacked body S1 and the second interlayer insulating layer IL2.

A surface IL1[SU] of the first interlayer insulating layer IL1 extends in the first direction DR1 and the second direction DR2 and faces in the third direction DR3. The plurality of conductive layers CDL[S], CDL[C], and CDL[D] are alternately arranged with the plurality of intervening interlayer insulating layers IIL in the third direction DR3 between the first interlayer insulating layer IL1 and the second interlayer insulating layer IL2. The plurality of conductive layers CDL[S], CDL[C], and CDL[D] and the plurality of intervening interlayer insulating layers IIL are divided into the first sub-gate stacked body S1 and the second sub-gate stacked body S2. The plurality of support structures SP are disposed in the first interlayer insulating layer IL1 and the first sub-gate stacked body S1, and the second sub-gate stacked body S2 extends to cover the plurality of support structures SP. The plurality of support structures SP includes at least one first support structure SP1 extending through the first sub-gate stacked body S1 adjacent to the first slit SI1, and at least one second support structure SP2 extending through the first sub-gate stacked body S1 adjacent to the second slit SI2.

The plurality of channel pillars CHP extend through the first interlayer insulating layer IL1, first sub-gate stacked body S1, second sub-gate stacked body S2, and second interlayer insulating layer IL2 of the gate stacked body ST. A memory layer ML is interposed between the gate stacked body ST and each channel pillar CHP.

Each channel pillar CHP includes a first portion P1 extending through the first interlayer insulating layer IL1, a second portion P2 extending through the second interlayer insulating layer IL2, and a third portion P3 extending between the first portion P1 and the second portion P2. The third portion P3 extends through the first sub-gate stacked body S1 and the second sub-gate stacked body S2. The channel pillar CHP includes a channel layer CLL forming the outer wall of each of the first portion P1, the second portion P2, and the third portion P3. In an embodiment, the channel layer CLL may be formed in a tubular shape. For example, the channel pillar CHP includes a core insulating layer CO and a capping pattern CAP that are disposed in a central area within a tubular pattern of the channel layer CLL.

The plurality of channel pillars CHP and the second interlayer insulating layer IL2 are covered with an insulating layer 81. The first slit SI1 and the second slit SI2 extend through the insulating layer 81. A bit line contact structure BCC is disposed in the insulating layer 81. The bit line contact structure BCC is coupled to the channel layer CLL of the channel pillar CHP. In an embodiment, the bit line contact structure BCC is electrically connected to the channel layer CLL of the channel pillar CHP via the capping pattern CAP.

Referring to FIG. 3, the plurality of conductive layers CDL[S], CDL[C], and CDL[D] include the source select gate layers CDL[S], the plurality of cell gate layers CDL[C], and the drain select gate layers CDL[D]. At least one of each source select gate layer CDL[S] and each drain select gate layer CDL[D] may be separated into select lines. In an embodiment, as shown in FIG. 3, each of the source select gate layers CDL[S] is separated into source select lines by the select gate separation structure SSI between the first slit SI1 and the second slit SI2.

Referring to FIG. 5A and FIG. 5C, according to an embodiment, the source select gate layers CDL[S] are separated into source select lines SSL by a source select gate separation structure SSI between the first slit SI1 and the second slit SI2. Each of the plurality of word lines WL formed of the plurality of cell gate layers CDL[C] continuously extends between the first slit SI1 and the second slit SI2 and is disposed over the source select gate separation structure SSI. The drain select line DSL formed from one of the drain select gate layers CDL[D] continuously extends between the first slit SI1 and the second slit SI2 and is disposed over the source select gate separation structure SSI. The gate array GA illustrated in FIG. 1A may be implemented utilizing the gate stacked body ST illustrated in FIG. 5A and FIG. 5C.

Referring to FIG. 5B, according to an embodiment, the drain select gate layers CDL[D] are separated into drain select lines DSL by the drain select gate separation structure DSI between the first slit SI1 and the second slit SI2. Each of the plurality of word lines WL formed of the plurality of cell gate layers CDL[C] continuously extends between the first slit SI1 and the second slit SI2 and is disposed below the drain select gate separation structure DSI. The source select line SSL formed from one of the source select gate layers CDL[S] continuously extends from the first slit SI1 toward the second slit SI2 and is disposed below the drain select gate separation structure DSI. The gate array GA illustrated in FIG. 1B may be implemented utilizing the gate stacked body ST illustrated in FIG. 5B.

Referring to FIG. 5A to FIG. 5C, the plurality of support structures SP extends through the conductive layers of the first sub-gate stacked body S1 and is disposed below the conductive layer of the second sub-gate stacked body S2. The conductive layer forming the first sub-gate stacked body S1 includes at least one source select gate layer CDL[S], and the conductive layers forming the second sub-gate stacked body S2 include at least one drain select gate layer CDL[D].

Referring to FIG. 5A, according to an embodiment, the first sub-gate stacked body S1 includes the source select gate layers CDL[S], and the second sub-gate stacked body S2 includes the plurality of cell gate layers CDL[C] and the drain select gate layers CDL[D]. In this example, the plurality of support structures SP are provided using a process of forming the source select gate separation structure SSI, and the plurality of support structures SP have substantially the same height as the source select gate separation structure SSI in the third direction DR3.

Referring to FIG. 5B and FIG. 5C, the plurality of cell gate layers CDL[C] is divided into a first group G1 and a second group G2. The first group G1 includes a first subset of the plurality of cell gate layers CDL[C] nearest or disposed near the source select gate layers CDL[S], and the second group G2 includes a second subset of the plurality of cell gate layers CDL[C] disposed between the first group G1 and the drain select gate layers CDL[D].

According to an embodiment, the first sub-gate stacked body S1 includes the first group G1 among the plurality of cell gate layers CDL[C] and the source select gate layers CDL[S]. The second sub-gate stacked body S2 includes the second group G2 among the plurality of cell gate layers CDL[C] and the drain select gate layers CDL[D]. In this example, the plurality of support structures SP extends in the third direction DR3 through the first group G1 of the plurality of cell gate layers CDL[C] as well as the source select gate layers CDL[S]. In this example, as shown in FIG. 5C, the plurality of support structures SP extends further in the third direction DR3 than the source select gate separation structure SSI extends in the third direction DR3.

Referring to FIG. 5A to FIG. 5C, as described with reference to FIG. 3, FIG. 4A, and FIG. 4B, the first portion P1 of each channel pillar CHP is formed having a narrower width than the width of the second portion P2. The third portion P3 of the channel pillar CHP may include various structures. In an embodiment, the third portion P3 include a first coupler P31 and a second coupler P32 as shown in FIG. 5A and FIG. 5C. The first coupler P31 extends between the first portion P1 and the second portion P2, and a width of the first coupler P31 is wider further away from the first portion P1 than closer to the first portion P1. The second coupler P32 extends between the first coupler P31 and the second portion P2, and a width of the second coupler P32 is narrower closer the first coupler P31 than further away from the first coupler P31. At a point or level where the first coupler P31 and the second coupler P32 meet, adjoin, or are coupled, the first coupler P31 has a wider width than the width of the second coupler P32. A corner CN is formed in the channel pillar CHP at this point or level.

Referring to FIG. 5C, according to an embodiment, the corner CN of the channel pillar CHP is located between the first group G1 and the second group G2 of the plurality of cell gate layers CDL[C].

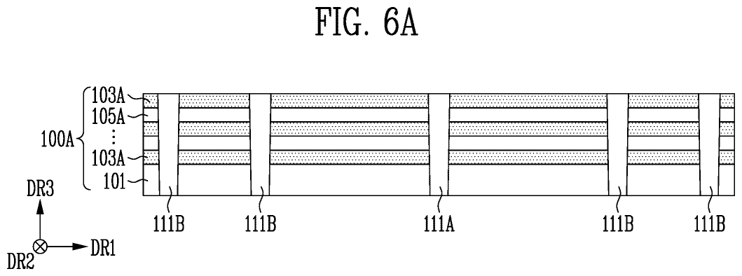

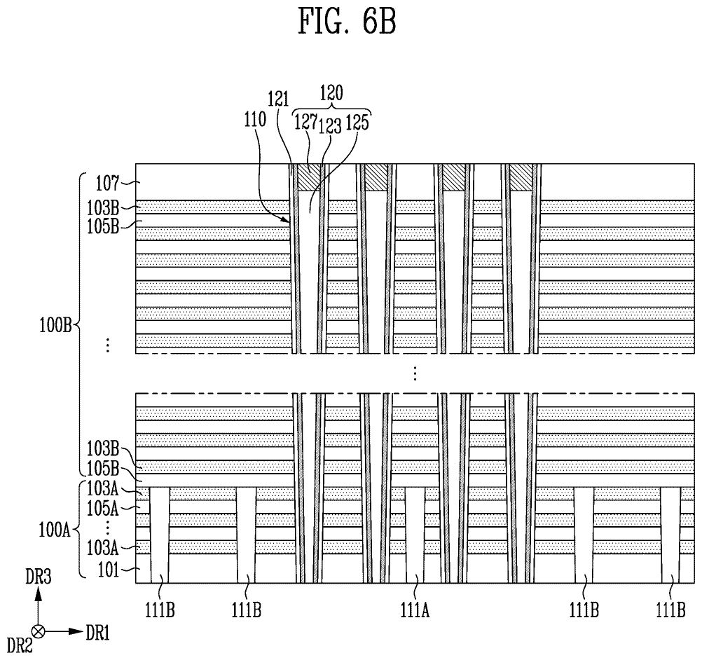

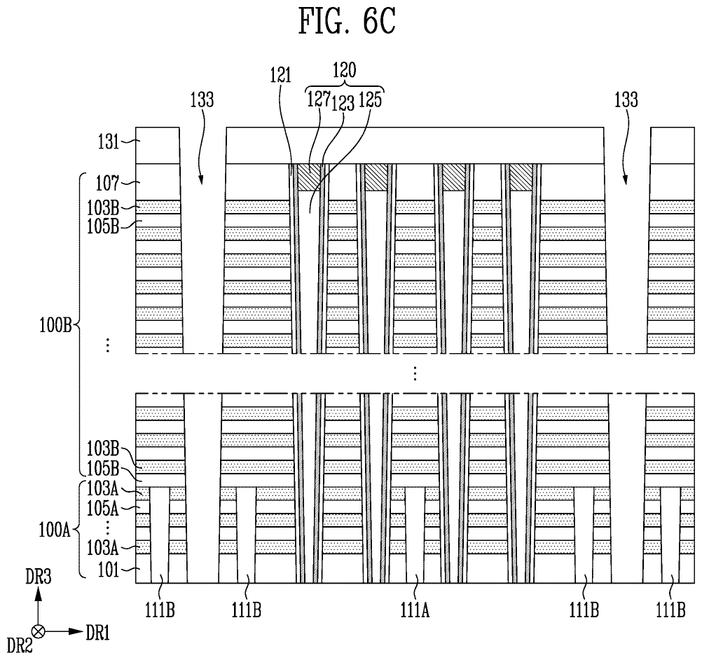

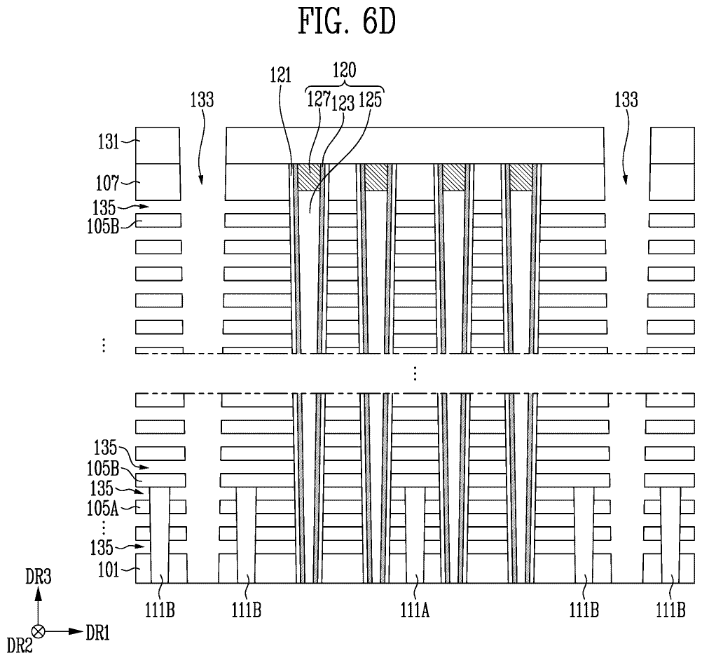

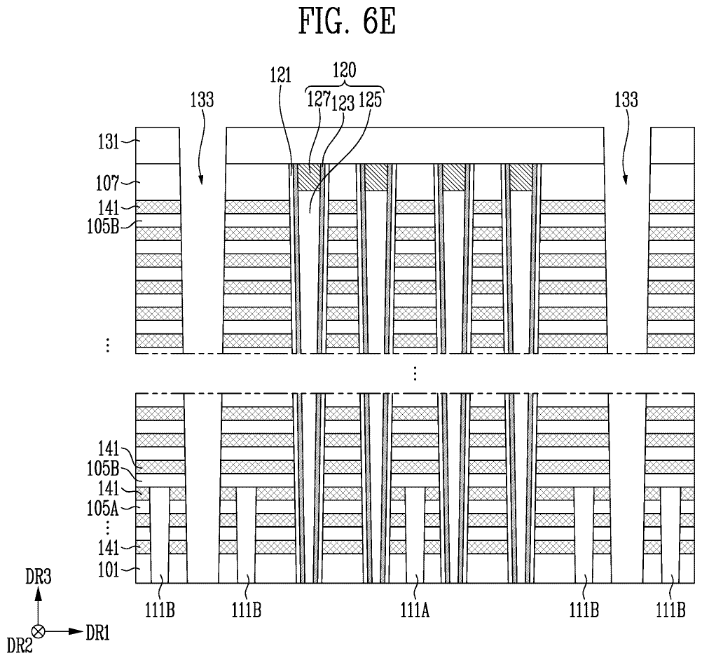

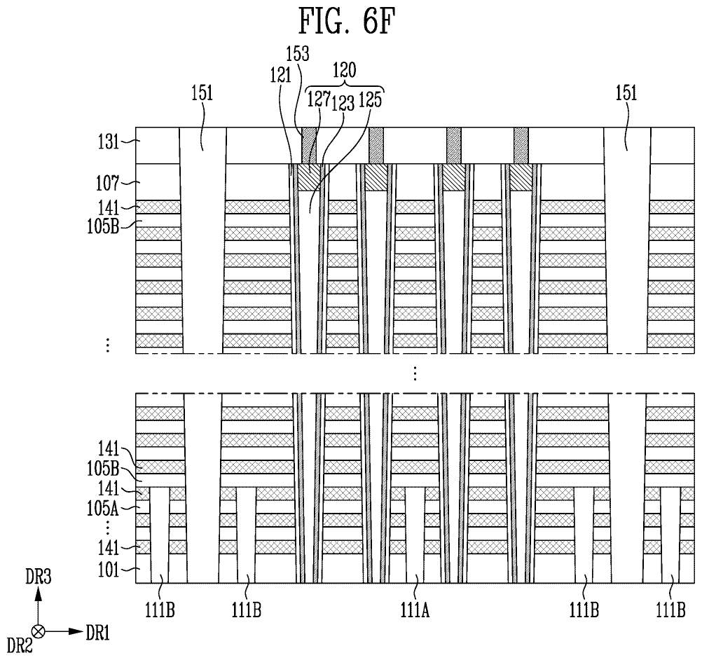

FIG. 6A to FIG. 6F are sectional views illustrating a semiconductor memory device formed utilizing a method of manufacturing a semiconductor memory device according to an embodiment of the present disclosure.

Referring to FIG. 6A, a first stacked body 100A may be formed over a lower structure (not illustrated). According to an embodiment, the lower structure may include the semiconductor substrate SUB including the plurality of transistors PTR shown in FIG. 2A and the doped semiconductor structure DPS shown in FIG. 2A. According to an embodiment, the lower structure may be a sacrificial substrate formed of a silicon wafer or the like.

The first stacked body 100A includes a first interlayer insulating layer 101, at least one first sacrificial layer 103A alternately disposed with at least one first intervening interlayer insulating layer 105A and disposed over the first interlayer insulating layer 101 in a stacking direction, such as the third direction DR3. The quantity of first sacrificial layers 103A may vary depending on the quantity of source select gate layers. In an embodiment, such as shown in FIG. 3, the first stacked body 100A includes three first sacrificial layers 103A that correspond to three source select gate layers CDL[S]. The first intervening interlayer insulating layers 105A are alternately disposed with the first sacrificial layers 103A in the stacking direction DR3.

The first sacrificial layer 103A is formed of a material having etch selectivity relative to the first interlayer insulating layer 101 and the first intervening interlayer insulating layer 105A. According to an embodiment, the first interlayer insulating layer 101 and the first intervening interlayer insulating layer 105A may include an insulating material such as a silicon oxide layer or a silicon oxynitride layer, and the first sacrificial layer 103A may include a sacrificial insulating material such as a silicon nitride layer.

Subsequently, a source select gate separation structure 111A extending through the first stacked body 100A is formed. In this example, a plurality of support structures 111B are formed. The plurality of support structures 111B extend through the first stacked body 100A. By forming the plurality of support structures 111B using and/or during the process of forming the source select gate separation structure 111A, the process of manufacturing the semiconductor memory device can be simplified.

The process of forming the source select gate separation structure 111A and the plurality of support structures 111B may include a process of forming a first mask pattern (not illustrated) including a trench and a plurality of openings on the first stacked body 100A, a process of etching the first stacked body 100A using the first mask pattern as an etch barrier, a process of filling etched areas of the first stacked body 100A with insulating material, and a process of removing the first mask pattern. The source select gate separation structure 111A is formed in an area corresponding to the trench of the first mask pattern, and the plurality of support structures 111B is formed in areas corresponding to the plurality of openings of the first mask pattern.

Referring to FIG. 6B, a second stacked body 100B is formed over the first stacked body 100A. The second stacked body 100B is formed to cover the source select gate separation structure 111A and the plurality of support structures 111B. The second stacked body 100B includes a plurality of second sacrificial layers 103B alternately disposed with a plurality of second intervening interlayer insulating layers 105B that are disposed over the first stacked body 100A in the stacking direction DR3, and a second interlayer insulating layer 107 disposed over an uppermost second sacrificial layer 103B among the plurality of second sacrificial layers 103B. The plurality of second sacrificial layers 103B may be formed of the same material as the first sacrificial layers 103A, and the plurality of second intervening interlayer insulating layers 105B and the second interlayer insulating layer 107 may be formed of the same material as the first intervening interlayer insulating layer 105A.

A plurality of channel holes 110 is formed by etching the first stacked body 100A and the second stacked body 100B using a second mask pattern (not illustrated) as an etch barrier. The plurality of channel holes 110 extends through the first stacked body 100A and the second stacked body 100B on both sides of the source select gate separation structure 111A.

The memory layer 121 is formed along an inner wall of each channel hole 110. The memory layer 121 includes a blocking insulating layer, a data storage layer, and a tunnel insulating layer. A channel pillar 120 is formed in the central area of the channel hole 110 within the memory layer 121.

According to an embodiment, the process of forming the channel pillar 120 includes forming a channel layer 123 along an inner wall of the memory layer 121, and filling the central area of the tubular structure of the channel layer 123 with a core insulating layer 125 and a capping pattern 127. The channel layer 123 may be formed of a semiconductor material such as silicon (Si), germanium (Ge), or a mixture thereof, which may be used for the channel area. The capping pattern 127 may be formed of a doped semiconductor layer. The second mask pattern (not illustrated) may be removed during the process of forming the channel pillar 120 or may be removed through a separate removal process.

Referring to FIG. 6C, an insulating layer 131 is formed over the second stacked body 100B and is disposed over the channel pillar 120. The insulating layer 131 may include a silicon oxide layer or the like.

A slit 133 is formed by etching the first stacked body 100A, the second stacked body 100B, and the insulating layer 131 through an etching process using a third mask pattern (not illustrated) as the etch barrier. The slit 133 is disposed between neighboring or consecutive rows of the support structures 111B.

Referring to FIG. 6D, the first sacrificial layers 103A and the plurality of second sacrificial layers 103B illustrated in FIG. 6C are removed through the slit 133. As a result, a plurality of horizontal spaces 135 are opened. The plurality of horizontal spaces 135 correspond to areas from which the first sacrificial layers 103A and the plurality of second sacrificial layers 103B illustrated in FIG. 6C are removed. The shape and structure of each horizontal space 135 is maintained by the channel pillars 120 as well as the support structures 111B.

Referring to FIG. 6E, a plurality of conductive layers 141 are formed in the plurality of horizontal spaces 135 illustrated in FIG. 6D.

Referring to FIG. 6F, a vertical structure 151 is formed in each slit 133. The vertical structure 151 may include an insulating layer that covers the sidewalls of the plurality of conductive layers 141. The vertical structure 151 may further include at least one of a conductive layer and a semiconductor layer in addition to, for example, within, the insulating layer.

A bit line contact structure 153 is formed. The bit line contact structure 153 extends through the first insulating layer 131 and is formed of a conductive material. The bit line contact structure 153 is coupled to the capping pattern 127 of the channel pillar 120.

Additional processes may vary depending on the design of the semiconductor memory device.

The semiconductor memory device illustrated in FIG. 3, FIG. 4A, and FIG. 4B may be formed using processes described with reference to FIG. 6A to FIG. 6F.

The semiconductor memory devices illustrated in FIG. 5A to FIG. 5C may be formed using processes described with reference to FIG. 6A to FIG. 6F. For example, the plurality of second intervening interlayer insulating layers 105B and the plurality of second sacrificial layers 103B of the second stacked body 100B illustrated in FIG. 6B may be divided into a first sub-group closest to the first stacked body 100A illustrated in FIG. 6B, a second sub-group disposed over the first sub-group, and a third sub-group disposed over the second sub-group. The second sacrificial layer included in each of the first sub-group and the second sub-group is replaced with the conductive layers used as the word lines, and the second sacrificial layers included in the third sub-group are replaced with the conductive layers used as the drain select lines.

The channel-hole forming process and the support-structure forming process may be designed in various ways, for example, including the first sub-group, the second sub-group, and the third sub-group.

According to an embodiment, the channel-hole forming process for the semiconductor memory device illustrated in FIG. 5A and FIG. 5C includes a process of forming a lower channel hole and a process of forming an upper channel hole. The process of forming the lower channel hole includes a process of forming the first sub-group, which is a section of the second stacked body 100B illustrated in FIG. 6B, over the first stacked body 100A illustrated in FIG. 6B, and a process of etching the first sub-group and the first stacked body 100A illustrated in FIG. 6B to form the lower channel hole. The process of forming the upper channel hole includes a process of filling the lower channel hole with a filling layer, a process of forming the second sub-group and the third sub-group, which are other sections of the second stacked body 100B illustrated in FIG. 6B, over the first sub-group, and a process of etching the second sub-group and the third sub-group to form the upper channel hole exposing the filling layer. The memory layer ML and the channel pillar CHP illustrated in FIG. 5A and FIG. 5C are formed after opening the lower channel hole by removing the filling layer through the upper channel hole.

According to an embodiment, the process of forming the support structure SP for the semiconductor memory device illustrated in FIG. 5B and FIG. 5C is performed after forming the first sub-group that is a section of the second stacked body 100B illustrated in FIG. 6B. In this example, the support structures 111B are formed to extend through the first sub-group and the first stacked body 100A illustrated in FIG. 6B. After forming the support structures 111B, the second sub-group and the third sub-group, which are other sections of the second stacked body 100B illustrated in FIG. 6B, are formed over the first sub-group. The support structures 111B may be formed using a separate process used to form the channel hole or may be formed using the process of forming the lower channel hole for the semiconductor memory device illustrated in FIG. 5C.

The source select gate separation structure 111B illustrated in FIG. 6A to FIG. 6F may be omitted, and the drain select gate separation structure DSI may be formed as illustrated in FIG. 5B. In an embodiment, the drain select gate separation structure DSI is formed through the third sub-group that is a section of the second stacked body 100B illustrated in FIG. 6B.

According to the above-described embodiments of the present disclosure, a support force may be reinforced or augmented by forming a plurality of support structures neighboring or near the slit during the process of manufacturing the semiconductor memory device, and space occupied by the stacked body adjacent to the slit may be efficiently utilized.

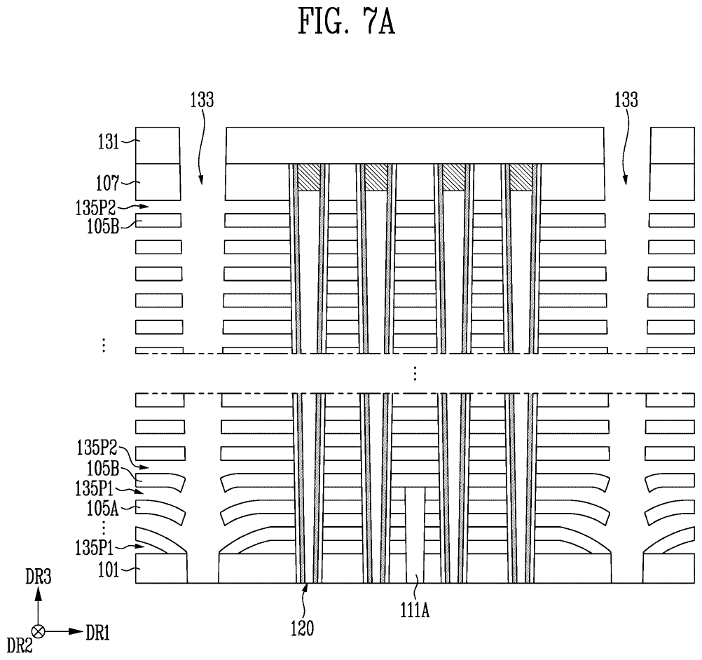

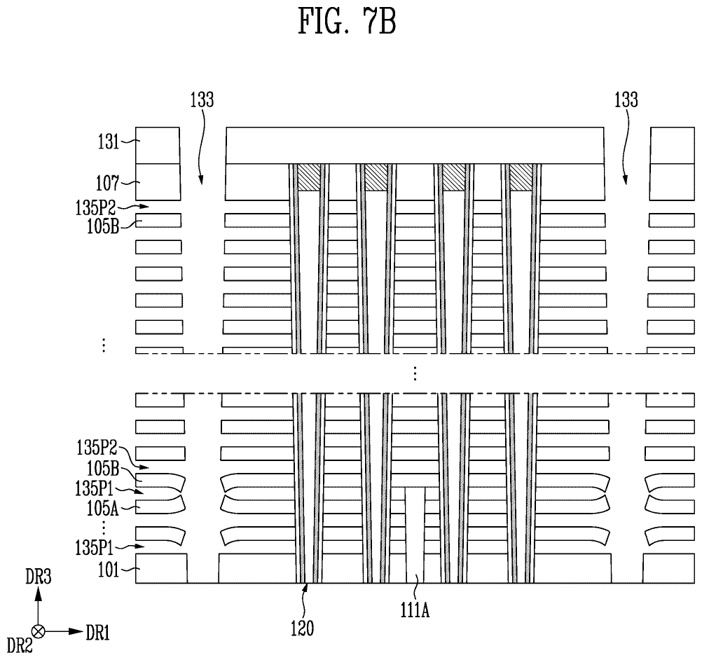

FIG. 7A and FIG. 7B are sectional views illustrating a semiconductor memory device formed utilizing processes of manufacturing a semiconductor memory device according to an embodiment excluding support structures.

Referring to FIG. 7A and FIG. 7B, the channel pillars 120 that extend through the first interlayer insulating layer 101, the first intervening interlayer insulating layers 105A, the plurality of second intervening interlayer insulating layers 105B, and the second interlayer insulating layer 107 and that are covered with the insulating layer 131 are formed using the processes described with reference to FIG. 6A to FIG. 6D. The slit 133 extends through the first interlayer insulating layer 101, the first intervening interlayer insulating layer 105A, the plurality of second intervening interlayer insulating layers 105B, and the second interlayer insulating layer 107. The source select gate separation structure 111A extends through the first interlayer insulating layer 101 and the first intervening interlayer insulating layer 105A.

A plurality of horizontal spaces 135P1 and 135P2 are opened in areas from which the first sacrificial layers of the first stacked body and the plurality of second sacrificial layers of the second stacked body are removed. The plurality of horizontal spaces 135P1 and 135P2 include the first horizontal spaces 135P1 and the second horizontal spaces 135P2. The first interlayer insulating layer 101 is closer to the first horizontal spaces 135P1 than to the second horizontal spaces 135P2. The width of at least one of the channel pillar 120 and the slit 133 is narrower closer to the first interlayer insulating layer 101 than the width of at least one of the channel pillar 120 and the slit 133 closer to the insulating layer 131. Thus, widths of the first intervening interlayer insulating layers 105A between the channel pillar 120 and the slit 133 are wider than widths of the second intervening interlayer insulating layers 105B between the channel pillar 120 and the slit 133. For this reason, the support force of the channel pillar 120 for the first intervening interlayer insulating layers 105A decreases closer to the slit 133, resulting in distortion of the shapes of the first horizontal space 135P1 and the shapes of some of the first intervening interlayer insulating layers 105A and the second intervening interlayer insulating layers 105B near the slit 133.

Compared to FIG. 6D, considering that the shapes of the first horizontal spaces 135P1 and the shapes of some of the first intervening interlayer insulating layers 105A and the second intervening interlayer insulating layers 105B near the slit 133 illustrated in FIG. 7A and FIG. 7B are distorted, the support structures 111B extend through the first intervening interlayer insulating layers 105A and are disposed near the slit 133, such that the shape distortion of the horizontal spaces 135, and the shapes of some of the first intervening interlayer insulating layers 105A and the second intervening interlayer insulating layers 105B, near the first interlayer insulating layer 101 may be reduced.

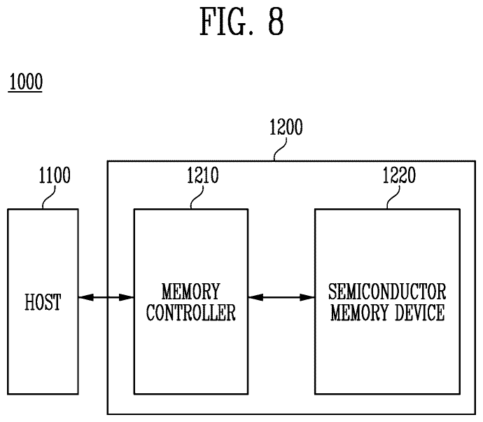

FIG. 8 is a block diagram illustrating an electronic system according to an embodiment of the present disclosure.

Referring to FIG. 8, the electronic system 1000 may be a computing system, a medical device, a communication device, a wearable electronic device, a memory system, and so forth. The electronic system 1000 includes a host 1100 and a storage device 1200.

The host 1100 stores data in the storage device 1200 or reads data stored in the storage device 1200 utilizing an interface. The interface may include at least one of a double data rate (DDR) interface, an universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA interface, a parallel-ATA interface, a small computer system interface (SCSI), an enhanced small disk interface (ESDI), an integrated drive electronics (IDE) interface, a Firewire interface, a universal flash storage (UFS) interface, and a nonvolatile memory express (NVMe) interface.

The storage device 1200 includes a memory controller 1210 and a semiconductor memory device 1220. According to an embodiment, the storage device 1200 may be a solid state drive (SSD) or a universal serial bus (USB) memory.

The memory controller 1210 stores data in the semiconductor memory device 1220 or reads data stored in the semiconductor memory device 1220 under the control of the host 1100.

The semiconductor memory device 1220 includes one memory chip or a plurality of memory chips. The semiconductor memory device 1220 stores data or outputs the stored data under the control of the memory controller 1210.

The semiconductor memory device 1220 may be a non-volatile memory device. The semiconductor memory device 1220 includes the gate stacked body enclosing the plurality of channel pillars as well as the plurality of support structures extending through a subset of layers of the gate stacked body at an edge of the gate stacked body.

According to the present disclosure, the structural stability of a semiconductor memory device may be improved by utilizing a one or more support structures.

What is claimed is:

1. A semiconductor memory device comprising:
a first interlayer insulating layer including a surface extending in a first direction and a second direction and facing a third direction;
a second interlayer insulating layer spaced apart from the first interlayer insulating layer in the third direction;
a plurality of channel pillars extending through the first interlayer insulating layer and the second interlayer insulating layer;
a first sub-gate stacked body enclosing the plurality of channel pillars between the first interlayer insulating layer and the second interlayer insulating layer;
a plurality of support structures arranged in a row near an edge of the first sub-gate stacked body and extending through the first interlayer insulating layer and the first sub-gate stacked body; and
a second sub-gate stacked body enclosing the plurality of channel pillars between the first sub-gate stacked body and the second interlayer insulating layer and covering the plurality of support structures.

2. The semiconductor memory device according to claim 1, wherein the first sub-gate stacked body comprises a source select line disposed between the first interlayer insulating layer and the second sub-gate stacked body.

3. The semiconductor memory device according to claim 1, wherein the second sub-gate stacked body comprises a plurality of word lines disposed between the first sub-gate stacked body and the second interlayer insulating layer and spaced apart from each other in the third direction.

4. The semiconductor memory device according to claim 1, further comprising:
a memory layer interposed between each of the plurality of channel pillars and the second sub-gate stacked body,
wherein the memory layer extends between each of the channel pillars and the first sub-gate stacked body.

5. The semiconductor memory device according to claim 1, wherein the first sub-gate stacked body extends between the plurality of support structures.

6. The semiconductor memory device according to claim 1,
wherein each of the plurality of channel pillars comprises a first portion extending through the first interlayer insulating layer, a second portion extending through the second interlayer insulating layer, and a third portion extending between the first portion and the second portion, and
wherein a width of the first portion is narrower than a width of the second portion.

7. A semiconductor memory device comprising:
a first interlayer insulating layer including a surface extending in a first direction and a second direction and facing a third direction;
a second interlayer insulating layer spaced apart from the first interlayer insulating layer in the third direction;
a plurality of conductive layers alternately arranged with a plurality of intervening interlayer insulating layers in the third direction and located between the first interlayer insulating layer and the second interlayer insulating layer;
a first slit and a second slit extending, in the third direction, through the first interlayer insulating layer, the plurality of conductive layers, the plurality of intervening interlayer insulating layers, and the second interlayer insulating layer, the first slit spaced apart from the second slit in the first direction;
a plurality of first support structures forming a first row near the first slit and a plurality of second support structures forming a second row near the second slit, wherein the plurality of first support structures and the plurality of second support structures extend through a first subset of the conductive layers nearest to the first interlayer insulating layer and a second subset of the conductive layers is disposed over a surface of each of the plurality of first support structures and a surface of each of the plurality of second support structures; and
a plurality of channel pillars disposed between the first row and the second row and extending, in the third direction, through the plurality of conductive layers, the plurality of intervening interlayer insulating layers, and the second interlayer insulating layer.

8. The semiconductor memory device according to claim 7, wherein:
the plurality of first support structures form the first row arranged in the second direction; and
the plurality of second support structures form the second row arranged in the second direction.

9. The semiconductor memory device according to claim 7, wherein the first subset of the conductive layers extends between consecutive first support structures in the second direction and extends between consecutive second support structures in the second direction.

10. The semiconductor memory device according to claim 7, wherein each of the plurality of first support structures and each of the plurality of second support structures comprise a sidewall surrounded by the first subset of the conductive layers.

11. The semiconductor memory device according to claim 7,
wherein each of the plurality of channel pillars comprises a first portion extending through the first interlayer insulating layer, a second portion extending through the second interlayer insulating layer, and a third portion extending between the first portion and the second portion, and wherein a width of the first portion is narrower than a width of the second portion.

12. The semiconductor memory device according to claim 7, wherein a width of each of the first slit and the second slit near the first interlayer insulating layer is narrower than a width of each of the first slit and the second slit near the second interlayer insulating layer.

13. The semiconductor memory device according to claim 7, wherein:
the plurality of conductive layers comprise:
a source select gate layer disposed near the first interlayer insulating layer;
a drain select gate layer disposed near the second interlayer insulating layer; and
a plurality of cell gate layers disposed between the source select gate layer and the drain select gate layer and forming a plurality of word lines between the first slit and the second slit, and
a source select gate separation structure extending through the source select gate layer to separate the source select gate layer into source select lines.

14. The semiconductor memory device according to claim 13, wherein the plurality of support structures extend through the source select gate layers.

15. The semiconductor memory device according to claim 14, wherein each of the plurality of support structures has substantially the same height as the source select gate separation structure.

16. The semiconductor memory device according to claim 14, wherein the plurality of support structures extends further in the third direction than the source select gate separation structure extends in the third direction and extends through a subset of the plurality of word lines.

17. The semiconductor memory device according to claim 13,
wherein the plurality of cell gate layers comprise a first group disposed near the source select gate layer and a second group disposed between the first group and the drain select gate layer,
wherein each of the plurality of channel pillars comprises a corner formed between the first group and the second group, and
wherein the plurality of support structures extend through the first group of the plurality of cell gate layers and are covered with the second group of the plurality of cell gate layers.

18. The semiconductor memory device according to claim 7, further comprising a memory layer interposed between each of the plurality of channel pillars and a stacked body comprising the plurality of conductive layers and the plurality of intervening interlayer insulating layers.

19. A semiconductor memory device comprising:
a stack comprising a first subset of layers and a second subset of layers, wherein the stack extends in a first direction between a first slit and a second slit, wherein the first slit and the second slit extend in a second direction;
a plurality of channel pillars extending through the stack in the third direction;
a first plurality of support structures disposed between the first slit and the plurality of channel pillars and extending through the first subset of layers in the third direction; and
a second plurality of support structures disposed between the second slit and the plurality of channel pillars and extending through the first subset of layers in the third direction;
wherein the second subset of layers is disposed in the third direction over the first subset of layers, the plurality of first support structures, and the plurality of second support structures.

20. The semiconductor memory device of claim 19, wherein the stack comprises a plurality of conductive layers alternately arranged with a plurality of intervening interlayer insulating layers in the third direction.
